(19) United States
(12) Patent Application Publication
(10) Pub. No.: US 2004/0232957 A1
(43) Pub. Date: Nov. 25, 2004

(54) Internal voltage generator for semiconductor device

(76) Inventor: Chang Ho Do, Kyoungki-do (KR)

Correspondence Address: LADAS & PARRY LLP, 224 SOUTH MICHIGAN AVENUE, SUITE 1200, CHICAGO, IL, 60604, US

(21) Appl. No.: 10/740,277

(22) Filed: Dec. 18, 2003

(30) Foreign Application Priority Data
May 21, 2003 (KR) 2003-32211

(51) Int. Cl. H03L 7/00

(52) U.S. Cl. 327/143

(57) ABSTRACT

Disclosed is an internal power voltage generator capable of preventing an abnormal variation of an internal voltage of a semiconductor device caused when external voltage is applied thereto. The internal power voltage generator includes a first voltage generator for receiving external power voltage so as to output a first voltage, a plurality of second voltage generators for receiving the first voltage so as to output second voltages different from each other, and

a plurality of third voltage generators corresponding to the second voltage generators, respectively, and outputting third voltages different from each other. Output terminals for the second voltages are interconnected to output terminals for the third voltages by common lines. When the internal power voltage generator is used, internal power voltages, which are relatively stable, are outputted in an early stage in which the external power voltage is applied. Particularly, the internal power voltage generator can prevent a back-bias voltage, which is a negative voltage, from being abnormally varied or increased due to coupling effect caused by parasitic capacity. Thus, the semiconductor device can reliably operate.

### BACKGROUND OF THE INVENTION

1. Field of the Invention

The present invention relates to an internal voltage generator for a semiconductor memory device, and more particularly to an internal voltage generator for preventing abnormal variation of an internal voltage caused by an external voltage applied to the internal voltage generator.

2. Description of the Prior Art

In general, a semiconductor device, particularly, a memory device of the semiconductor device receives an external power voltage VDD in order to generate a plurality of internal power voltages to be used. Further, in the early stage of external power supply, the internal power voltages are variously generated. The internal power voltages represent a voltage VCP used as a plate voltage of a memory cell capacitor, a bit-line precharge voltage VBLP, and a body voltage VBB of a memory cell transistor, etc. Herein, an internal power voltage generator, which generates such internal power voltages, does not normally operate when external power is initially applied and increased, because the internal power voltage generator has an unstable bias state. Therefore, the internal power voltages outputted from the internal power voltage generator are also unstable.

As described above, when the early internal power voltages are unstable, latch-up may occur in the memory device. In addition, the latch-up may cause defect of the memory device.

Particularly, a memory core area may have significant problem. That is, when the back-bias internal power voltage VBB, which is used as a body voltage of the memory cell transistor, abnormally varies, the abnormal variation may cause an abnormal operation of the memory device. The abnormal variation of the back-bias internal power voltage VBB may be mainly caused by other internal power voltage adjacent to the back-bias internal power voltage VBB, for instance, the bit-line precharge internal voltage VBLP. That is, when the early bit-line precharge internal voltage VBLP is increased due to effect of parasitic capacity formed between the back-bias internal power voltage VBB and the bit-line precharge internal voltage VBLP, the back-bias internal power voltage VBB is also increased due to coupling effect. Particularly, since the memory device is recently high-integrated, when the bit-line precharge internal voltage VBLP and the plate voltage VCP of the memory cell capacitor are increased, the back-bias internal power voltage VBB may be subject to the abnormal variation due to effect of parasitic capacity formed between the back-bias internal power voltage VBB and the bit-line precharge internal voltage VBLP or the plate voltage VCP of the memory cell capacitor, that is, the back-bias internal power voltage VBB is increased due to coupling effect.

In order to solve these problems, in the prior art, internal power voltages (e.g. VBB, VBLP, and VCP) are connected to a ground voltage Vss for an early predetermined period, in which external power is applied. However, when an internal power voltage generator starts its operation in such a manner that the back-bias internal power voltage VBB is shifted into a negative voltage, and the bit-line precharge internal voltage VBLP and the plate voltage VCP of the memory cell capacitor are shifted into a positive voltage, mutual shift operations are interfered by parasitic capacity formed therebetween. In an extreme case, the back-bias internal power voltage VBB, which is an output voltage of the internal power voltage generator having relatively low driving ability, may rise to the positive voltage and then descend to the negative voltage. Accordingly, when the back-bias internal power voltage VBB is increased for a predetermined interval, latch-up may occur in the memory device, and therefore, the memory device has a fatal defect.

### SUMMARY OF THE INVENTION

Accordingly, the present invention has been made to solve the above-mentioned problems occurring in the prior art, and it is an object of the present invention to provide an internal power voltage generator capable of allowing a memory device to be stably operated by restricting an increase of an internal voltage (for example, VBB), which must shift into a negative voltage due to a coupling effect of parasitic capacity, through operating internal power voltage generators after increasing initial values of internal power voltages, which are increased into a positive voltage, for a predetermined time period when external power voltage is applied.

In order to achieve the above objects, according to one aspect of the present invention, there is provided an internal power voltage generator in a semiconductor device comprising: a first voltage generator for receiving external power voltage so as to output a first voltage; a plurality of second voltage generators for receiving the first voltage so as to output second voltages different from each other; and a plurality of third voltage generators corresponding to the second voltage generators, respectively, and outputting third voltages different from each other, wherein output terminals for the second voltages are interconnected to output terminals for the third voltages by common lines.

In the present invention, the first voltage generator outputs ground potential before a predetermined time lapses after the external power voltage is applied, and outputs the external power voltage after the predetermined time lapses.

In the present invention, the second voltage is internal power of the semiconductor device before the predetermined time lapses, and the third voltage is internal power of the semiconductor device after the predetermined time lapses.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram of an internal power voltage generator in a memory device according to an embodiment of the present invention;

FIG. 2 is a graph of voltage outputted from the internal power voltage generator in FIG. 1; and

FIG. 3 is a circuit diagram of the second voltage generator in FIG. 2.

### DETAILED DESCRIPTION OF THE PREFERRED EMBODIMENTS

Hereinafter, a preferred embodiment of the present invention will be described with reference to the accompanying drawings.

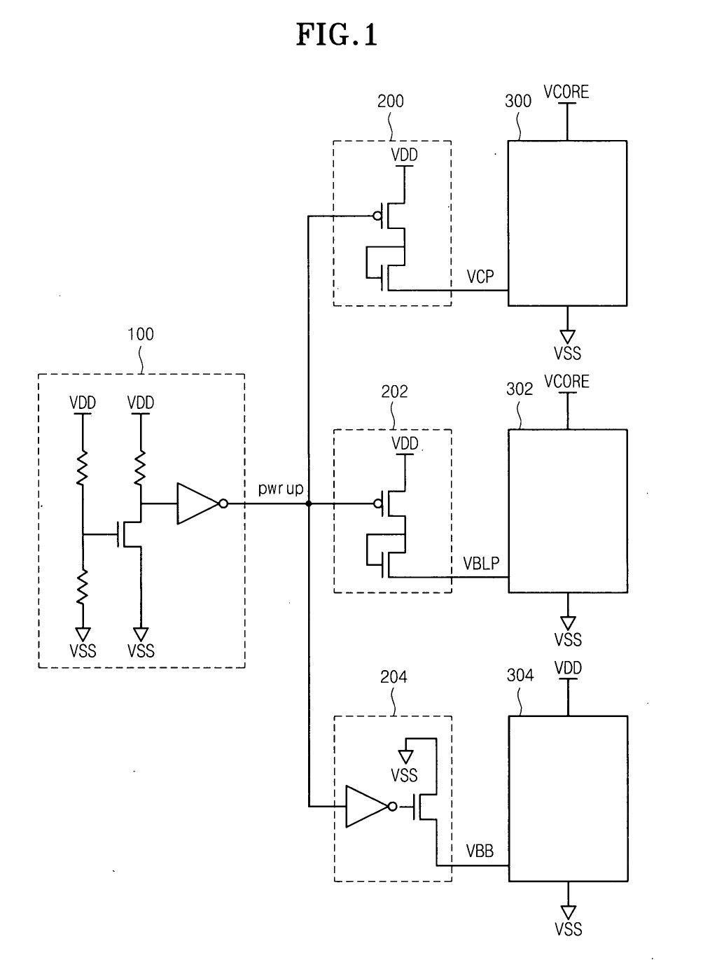

FIG. 1 is a block diagram of an internal power voltage generator in a memory device according to an embodiment of the present invention.

As shown in FIG. 1, the internal power voltage generator in the memory device according to the present invention, which receives an external power voltage so as to generate a plurality of internal power voltages, includes a first voltage generator 100, a plurality of second voltage generators 200, 202 and 204, and a plurality of third voltage generators 300, 302 and 304. The first voltage generator 100 receives the external power voltage to output a first voltage ‘pwrup’. The second voltage generators 200, 202 and 204 respectively receive the first voltage ‘pwrup’ outputted from the first voltage generator 100, and then output second voltages different from each other, that is, VCP, VBLP, and VBB which are internal voltages. The third voltage generators 300, 302 and 304 correspond to the second voltage generators 200, 202 and 204, respectively, and then, output third voltages, that is, VCP, VBLP, and VBB which are internal voltages. Herein, output terminals of the second voltages are mutually connected to output terminals of the third voltages by common lines.

The first voltage generator 100 is a general power-up voltage generator generating a power-up voltage when the external power voltage is applied thereto. Herein, since the power-up voltage generator is well known to those skilled in the art, detailed description will be omitted below.

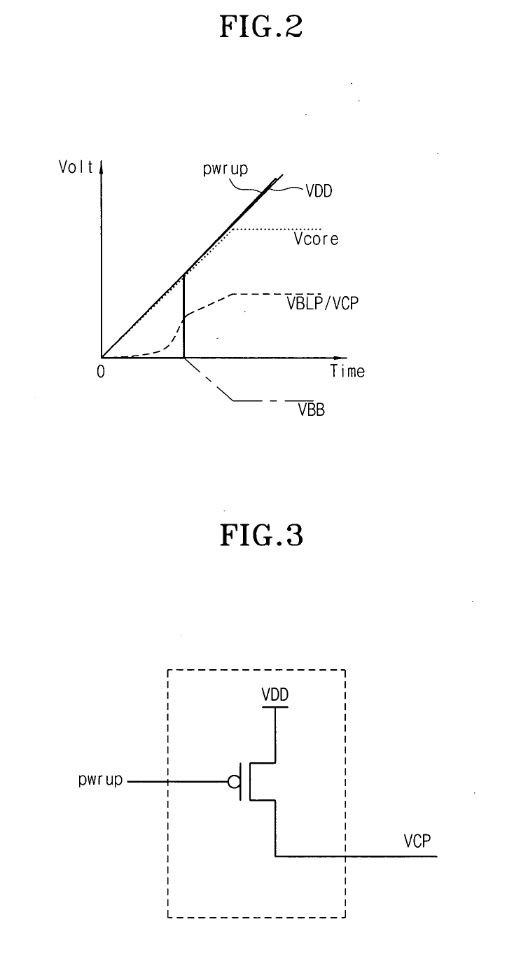

In operation, after the external power voltage is applied, the first voltage generator 100 actually outputs a ground voltage until a predetermined time lapses. That is, a VDD voltage of the first voltage generator 100 is near zero in an early transient stage in which the external power voltage is applied and increased. Further, since an inverter biased by the external power voltage does not actually operate, the first voltage generator 100 outputs the ground voltage as the output voltage ‘pwrup’. This description can be more easily seen from a view showing a waveform of the external power voltage and the internal power voltage as shown in FIG. 2. In FIG. 2, the power-up voltage indicated by a thick line keeps the ground voltage until a predetermined time lapses and follows the external power voltage after a predetermined time lapses. Herein, the aforementioned predetermined time represents time required for the power-up voltage to arrive at the external power voltage.

Next, as it can be seen from FIG. 1, the power-up voltage, which is the output voltage of the first voltage generator 100, is applied to the plurality of second voltage generators 200, 202 and 204. Herein, each of the second voltage generators is an apparatus, which outputs the internal power voltage until the power-up voltage reaches the external power voltage. Referring to FIG. 2, it can be understood that the internal power voltages VBLP, VCP and VBB actually represent the ground voltages when the power-up voltage, which is the output voltage of the first voltage generator 100, is in the ground voltage state.

The second voltage generators 200 and 202 of the second voltage generators, which output the memory cell plate voltage VCP and the bit-line precharge voltage VBLP shifted into the positive voltage when the external power voltage is applied, respectively include a PMOS transistor and an NMOS transistor connected in series with each other. A source terminal of the PMOS transistor, which receives the power-up voltage ‘pwrup’ through a gate terminal, is connected to the external power voltage VDD. A drain terminal of the PMOS transistor is connected to a drain terminal of the NMOS transistor. In the NMOS transistor, the drain terminal is connected to a gate terminal. Further, the NMOS transistor outputs a predetermined voltage through a source terminal. Herein, the NMOS transistor outputs the internal power voltages VCP and VBLP through the source terminal as an output voltage for a predetermined time until the power-up voltage ‘pwrup’ reaches the external power voltage. In this time, the internal power voltages VCP and VBLP can be seen from FIG. 2.

The second voltage generator 204 of the second voltage generators, which outputs the back-bias voltage VBB shifted into the negative voltage when the external power voltage is applied, includes an inverter and an NMOS transistor. An input terminal of the inverter receives the power-up voltage. ‘pwrup’ and an output terminal of the inverter is connected to a gate terminal of the NMOS transistor. A drain terminal of the NMOS transistor is connected to a ground voltage and a source terminal, which is an output terminal, of the NMOS transistor is connected to an output terminal of the third voltage generator 304. Herein, the NMOS transistor outputs internal power voltage VBB through the source terminal as an output voltage for a predetermined time until the power-up voltage ‘pwrup’ reaches the external power voltage. In this time, the internal power voltages VCP and VBLP can be seen from FIG. 2.

In operation, the second voltage generators 200 and 202 output the early internal power voltages VCP and VBLP for a predetermined time until the power-up voltage ‘pwrup’ reaches the external power voltage. When the early power-up voltage ‘pwrup’ is the ground voltage Vss, the PMOS transistor is turned on and transmits the external power voltage VDD to the drain terminal of the PMOS transistor. Herein, when a drain voltage of the PMOS transistor exceeds a threshold voltage Vth of the NMOS transistor, the NMOS transistor is turned on and outputs a VDD-Vth through the source terminal of the NMOS transistor. These voltages are the early internal power voltages VCP and VBLP. Thereafter, when the power-up voltage ‘pwrup’ is shifted into the external power voltage VDD after a predetermined time lapses, that is, when the power-up voltage ‘pwrup’ reaches the external power voltage VDD, the PMOS transistor is turned off, and the internal power voltages VCP and VBLP are prevented from being affected by the second voltage generators 200 and 202. From this time, the internal power voltages VCP and VBLP outputted from the third voltage generators 300 and 302 are used in the semiconductor device. In reference, the third voltage generators 300, 302 and 304 are general apparatuses, which are used in a semiconductor memory device, and can be variously embodied by those skilled in the art. Further, since the basic concept of the present invention is obviated from internal circuits of the third voltage generators, the description about the construction of the internal circuits will be omitted below.

Hereinafter, an operation of the second voltage generator 204 shown in FIG. 1 will be described.

The second voltage generator 204 is an apparatus outputting the early internal power voltage VBB for a predetermined time until the power-up voltage reaches the external power voltage. As described in the prior art, in order to prevent the internal power voltage VBB from rising when the external power voltage is increased due to effects of parasitic capacity, etc., when the external power voltage VDD exceeds the threshold voltage Vth of the NMOS transistor in a state in which the early power-up voltage ‘pwrup’ is the ground voltage, the ground voltage Vss is connected to a source terminal, which is an output terminal of the early internal power voltage, of the NMOS transistor, and therefore the internal power voltage VBB is stabilized. Thereafter, when the power-up voltage ‘pwrup’ reaches the external power voltage after a predetermined time lapses, the NMOS transistor is turned off, and the internal power voltage VBB is determined by an output of the third voltage generator 304. As it can be seen from FIG. 2, the voltage generator 204, which is an initialization circuit of the internal power voltage according to the present invention, is used, thereby preventing abnormal increase of the back-bias voltage VBB from occurring.

As described above, in the present invention, before a predetermined time lapses, that is, the power-up voltage ‘pwrup’ reaches the external power voltage, the internal power voltage of the semiconductor device is a voltage outputted from the second voltage generator 204. Further, after a predetermined time lapses, the internal power voltage of the semiconductor device is a voltage outputted from the third voltage generator 304. Accordingly, in the present invention, abnormal variation of the internal power voltage does not occur for a predetermined time just after the external power voltage is applied. Particularly, the back-bias voltage is stabilized.

FIG. 3 is a circuit diagram of the second voltage generators 200 and 202 according to another embodiment of the present invention. As shown in FIG. 3, each second voltage generator is constructed by a PMOS transistor, which receives a power-up voltage ‘pwrup’ through a gate terminal. A source terminal of the PMOS transistor is connected to an external power voltage and a drain terminal of the PMOS transistor is an output terminal.

In operation, when the early power-up voltage is ground voltage, the PMOS transistor is turned on. Further, after a predetermined time has passed and the power-up voltage comes into an external power voltage VDD, the PMOS transistor is turned off. That is, early internal power voltages VCP and VBLP are connected to the external power voltage VDD and move to a target value by the third voltage generator 304 when the power-up voltage is shifted into the external power voltage.

As described above, when an internal power voltage generator according to the present invention is used, relatively stable internal power voltages- can be outputted in an early stage of the external power voltage. Particularly, the internal power voltage generator can prevent the back-bias voltage, which is the negative voltage, from being abnormally varied or increased due to the coupling effect caused by the parasitic capacity, etc. Accordingly, the semiconductor device can reliably operate.

The preferred embodiment of the present invention has been described for illustrative purposes, and those skilled in the art will appreciate that various modifications, additions and substitutions are possible, without departing from the scope and spirit of the invention as disclosed in the accompanying claims.

What is claimed is:

1. An internal power voltage generator in a semiconductor device, the internal power voltage generator comprising:
a first voltage generator for receiving external power voltage so as to output a first voltage;
a plurality of second voltage generators for receiving the first voltage so as to output second voltages different from each other; and
a plurality of third voltage generators corresponding to the second voltage generators, respectively, and outputting third voltages different from each other,
wherein output terminals for the second voltages are interconnected to output terminals for the third voltages by common lines.

2. The internal power voltage generator in a semiconductor device as claimed in claim 1, wherein the first voltage generator outputs ground potential before a predetermined time lapses after the external power voltage is applied, and outputs the external power voltage after the predetermined time lapses, the predetermined time representing time required for the first voltage to come into the external power voltage.

3. The internal power voltage generator in a semiconductor device as claimed in claim 2, wherein the second voltage is internal power of the semiconductor device before the predetermined time lapses, and the third voltage is internal power of the semiconductor device after the predetermined time lapses.

4. The internal power voltage generator in a semiconductor device as claimed in claim 2 or 3, wherein the plurality of second voltage generators include a plurality of third voltage generators for outputting a positive voltage when the external power voltage is applied, and a plurality of fourth voltage generators for outputting a negative voltage when the external power voltage is applied.

5. The internal power voltage generator in a semiconductor device as claimed in claim 4, wherein each fourth voltage generator includes an inverter for receiving the first voltage and an NMOS transistor for receiving an output signal of the inverter through a gate terminal, a drain terminal of the NMOS transistor is connected to the ground voltage, and an output voltage of a source terminal of the NMOS transistor is the second voltage.

6. The internal power voltage generator in a semiconductor device as claimed in claim 4, wherein each third voltage generator includes a PMOS transistor and an NMOS transistor which are connected in series with each other, the first voltage is applied to a gate terminal of the PMOS transistor, the external power voltage is applied to a source terminal of the PMOS transistor, a drain terminal of the PMOS transistor is connected to a drain terminal of the NMOS transistor, the drain terminal of the NMOS transistor is connected to a gate terminal of the. NMOS transistor, and a voltage outputted from a source terminal of the NMOS transistor is the second voltage.

7. The internal power voltage generator in a semiconductor device as claimed in claim 4, wherein each third voltage generator includes a PMOS transistor, the first voltage is applied to a gate terminal of the PMOS transistor, the external power voltage is applied to a source terminal of the PMOS transistor, and a voltage outputted from a drain terminal of the PMOS transistor is the second voltage.
